(19) United States
(12) Patent Application Publication
(10) Pub. No.: US 2024/0288510 A1
(43) Pub. Date: Aug. 29, 2024

(54) AUXILIARY MULTIPOLAR DEVICE FOR TESTING ELECTRICAL INSTRUMENTS

(71) Applicant: Meliton Angeles Martinez, Oaxaca (MX)

(72) Inventor: Meliton Angeles Martinez, Oaxaca (MX)

(21) Appl. No.: 18/568,903

(22) PCT Filed: Jun. 6, 2022
(86) PCT No.: PCT/MX2022/050045

§ 371 Date: Dec. 11, 2023

(30) Foreign Application Priority Data
Jun. 17, 2021 (MX) MX/A/2021/007385

(51) Int. Cl. G01R 31/56

(52) U.S. Cl. CPC G01R 31/56

(57) ABSTRACT

An auxiliary multipolar device for testing electrical instruments including a test block (DAPRE) and a test paddle (DIPSE), configurable from 4 to 36 poles, with auxiliary contacts that detect the insertion of the paddle into the block, and a mechanism to activate the short-circuiting of the currents of the primary equipment and to open the contacts on the instrument side independently and uninterruptedly, where the contacts reduce their resistance, the thermal power dissipated, and prolong their useful life, reducing the friction caused by the movement of the tooth of the paddle. The device has a self-locking activation system, which is deactivated by one or more triggers, allowing the insertion and extraction of the paddle in discrete steps, to produce the operating sequence of the contacts, preventing involuntary operations and allowing tests to be performed reliably.

### CROSS REFERENCE TO RELATED APPLICATION

This application is a national stage entry of PCT/MX2022/0500045 filed Jun. 6, 2022, under the International Convention and claiming priority over Mexican Patent Application No. MX/a/20221/007385 filed Jun. 17, 2021.

### BACKGROUND OF THE INVENTION

An industrial electrical system also known as a power electrical system typically has an open loop control interface, whose inputs are signals from potential transformers and current transformers, whose function is to scale the electrical signals of the power line. medium, high and extra high voltage, to be connected to measuring instruments that work with low and reliable levels of voltage and current; and its control outputs are direct current signals to power the actuators that open the power switches. These actuators are known as trip coils.

Occasionally, maintenance work is required to validate, adjust or reconfigure the instrument parameters. This maintenance must be able to be carried out whether or not the system is in service, so the installations require means that allow opening the interface between the transformers and actuators (Primary Equipment Side) and the measurement and control instruments (Instrument Side); in addition to connecting the instruments to a second auxiliary interface through which operators can inject current and voltage test signals to the instruments and validate the correct operation of the shots.

Its complexity lies in the fact that this switching must be done sequentially and without disturbing the normal operation of the power system when it is in service, since it can produce a false trip order to the switches and affect the operation of the entire system at high costs electrical network. A very common practice is to integrate into the installation a device that is generically called a test block that normally keeps the interface between the primary equipment side and the instrument side closed; which works in conjunction with a second device called a test paddle that serves as the auxiliary interface and which, when inserted into the test block, disconnects the interface between the instrument side and the primary equipment side; and connects the instrument side to the auxiliary interface of the paddle.

The sequence for opening the interface between the primary equipment side and the instrument side consists of the following steps:
1.—interruption of the trigger signals.
2.—Short-circuit the input and return of the current signals on the primary equipment side, since the current signals of a current transformer when opened produce electric arcs that put facilities and human lives at risk, in addition to overload and reduce the useful life of the transformer.
3.—Interruption of the current circuits towards the Instrument side.
4.—Interruption of the potential circuits towards the instrument side.

Currently, the test blocks and paddles on the market work in a similar way, differing in the degree of security both in their normal operation and during the interface change, which is a determining factor in their price. Due to this, the innovations developed are valuable for competitiveness and are described in this patent, which takes reference from applications MX 305808 B and MX 358720 B, which already has auxiliary contacts through micro switches that identify whether the paddle is inserted into the block.

The problems these devices currently face are:
1.—Shorting the input and return of the current signals and interrupting the current signals are dependent actions, since the same movement of the contact terminals on the instrument side is used to carry out both actions, this prevents carrying out the sequence of operation with the required discrete intervals.
2.—The contact terminals have a silver coating on their entire surface that improves their electrical characteristics, which represents high manufacturing costs since they are technically only required at the contact points and the useful life of the contact is limited to wear due to friction suffered by the coating.
3.—The operation sequence must be carried out manually, so it depends on the expertise of user in its handling and is susceptible to errors.
4.—The test blocks are required from 4 to 36 poles, but the architecture of the paddles described in the mentioned patents requires exclusive parts to assemble paddles with a different number of poles, which increases production costs.
5. The signals may be exposed to disturbances due to accidental contact of the operators with the paddle inserted in the block and the block being in service.

### SUMMARY OF THE INVENTION

The present invention relates to an auxiliary multipolar device for testing electrical instruments including a test block (DAPRE) and a test paddle (DIPSE), configurable from 4 to 36 poles, with auxiliary contacts that detect the insertion of the paddle into the block, and a mechanism to activate the short-circuiting of the currents of the primary equipment and to open the contacts on the instrument side independently and uninterruptedly, where the contacts reduce their resistance, the thermal power dissipated, and prolong their useful life, reducing the friction caused by the movement of the tooth of the paddle. The device has a self-locking activation system, which is deactivated by one or more triggers, allowing the insertion and extraction of the paddle in discrete steps, to produce the operating sequence of the contacts, preventing involuntary operations and allowing tests to be performed reliably.

### BRIEF DESCRIPTION OF THE FIGURES

FIG. 1 Assembly diagram of a 10-pole block with the architecture of a multipole block;

FIG. 2 Set of electrical contacts for a current signal arranged in a block-A container;

FIG. 3 Set of electrical contacts of a potential signal arranged in a block-B container;

FIG. 4 Set of electrical contacts of a trigger signal arranged in a block-A container;

FIG. 5 Detail of a bimetallic copper-silver rivet arranged in a current terminal;

FIG. 6a shows a comparative diagram of positioning of the current and potential trigger contacts along the tooth displacement corridor showing a secondly the short contacts, elements (18) and (20) close when the tooth crosses the line;

FIG. 6b shows a comparative diagram of positioning of the current and potential trigger contacts along the tooth displacement corridor showing a thirdly the current contacts (40) are opened when the tooth crosses the line;

FIG. 6c shows a comparative diagram of positioning of the current and potential trigger contacts along the tooth displacement corridor showing a fourthly the potential contacts (41) are opened when the tooth crosses the line (D) at the end of the corridor (19);

FIG. 7 Assembly diagram of a 10-pole paddle with the architecture of a multipolar paddle; and

FIG. 8 Anchoring insurance mechanism of a multipolar paddle.

### DETAILED DESCRIPTION OF THE INVENTION

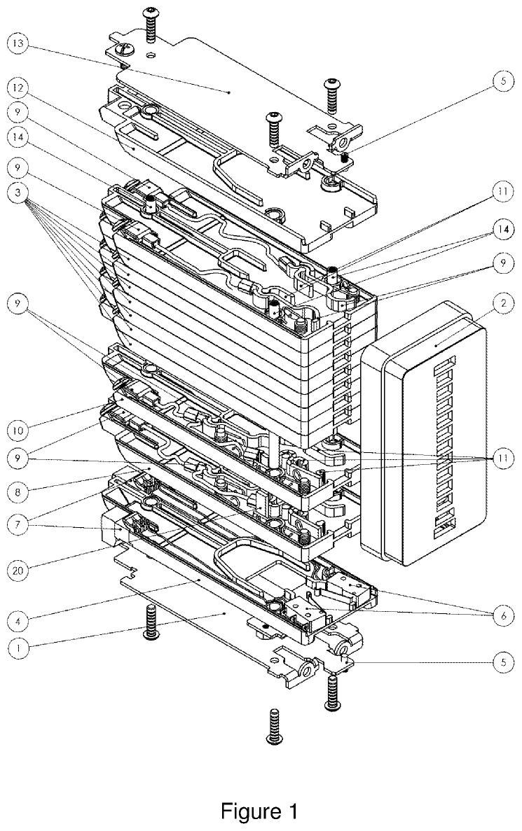

Auxiliary device for testing electrical instruments (FIG. 1) based on patent MX 358720 B auxiliary device for testing 24-pole electrical instruments, from which it takes the architecture of alternating type A and type B containers stacked to form a block on the back of which electrical terminals are housed and the sets of contacts for control, current and potential signals can be housed inside; with commercial screws that do not require special tools or special means to be connected, the electrical circuits of the control signals, current and potential are assembled with terminals made of copper sill bonded by copper staples to flexible copper cable; short-circuit bridges are copper sill that cross the current signal chambers of the same group of currents; on the front part it is covered with an element that we have called “bastiplas”; with metal supports at the ends that hold the containers together, and the “bastiplas” to the block, and house the mounting locks to the cabinet; with the lever microswitches placed on the block at the beginning of the paddle guide stroke whose contacts are used to alarm external equipment that the paddle has made contact with the block; The paddle changes its architecture but retains the same characteristics of the teeth to be compatible with blocks from other generations.

### Block

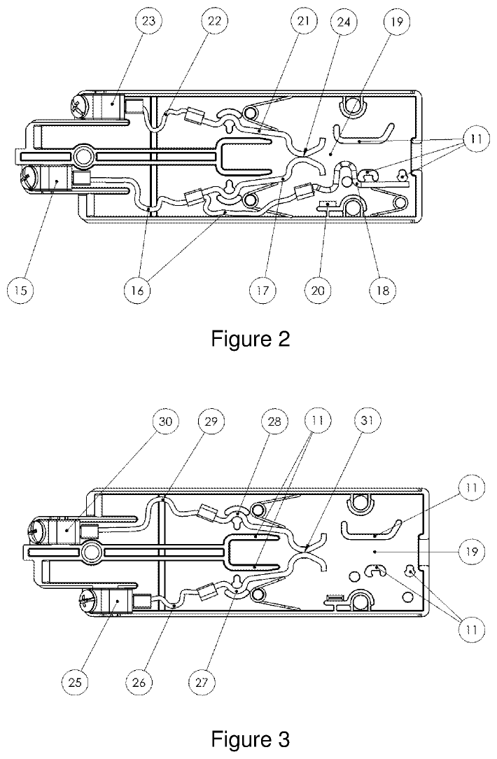

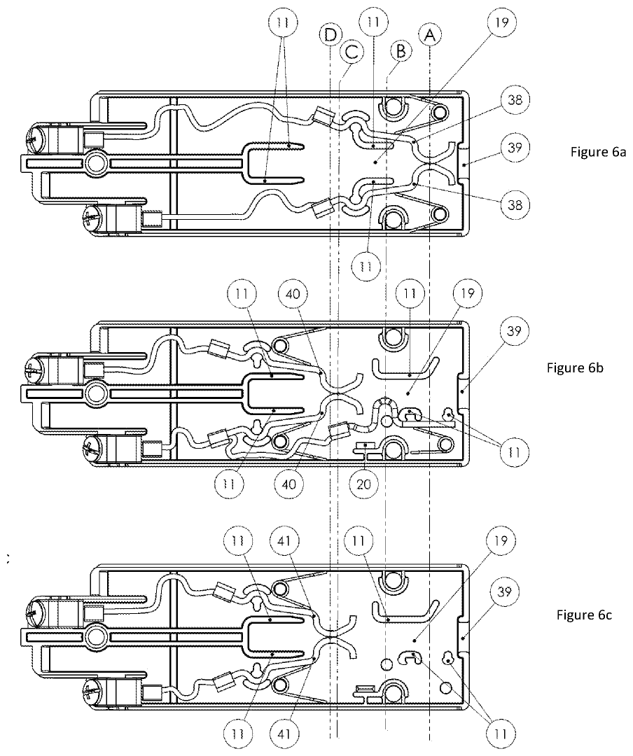

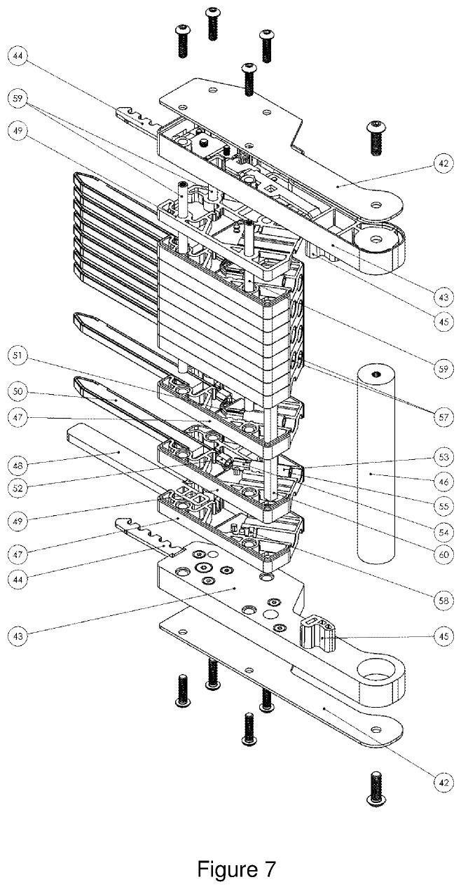

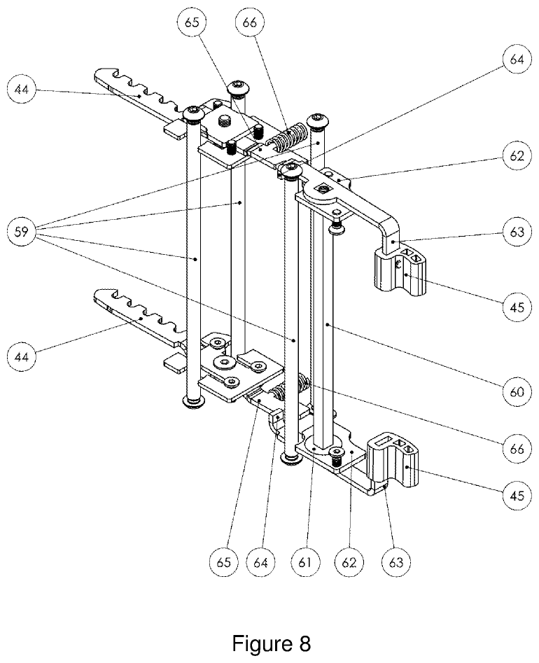

According to FIG. 1, the assembly of the block requires a lower metal base (1) that has a fold like tabs with two holes to be fixed by means of screws to the frame or “bastiplas” (2) and three holes to be screwed to the container assembly (3); followed by a block-base container (4) that with its lower cavity together with the lower metal base (1) forms a chamber that receives and protects the ratchet (44) (FIGS. 7 and 8) of the paddle, where it is It houses a bolt (5) embedded in the lower metal base (1) that serves as an anchor to the ratchet (44) (FIG. 7), and in its upper cavity it houses the auxiliary contact circuit that consists of two micro switches (6) opposing levers that serve as presence sensors of the guide (48) (FIG. 7) of the paddle when it is inserted into the block and whose terminals are each connected to bipolar plug-in type connectors (7); a block-A container (8) superimposed on the block-base type container (4) that with its lower cavity complements the housing chamber for the auxiliary contacts and its upper cavity serves to receive the first set of electrical contacts (9); a block-B container (10) superimposed on the block-A container (8) with its lower cavity complements the housing chamber of the first set of electrical contacts (9) and in its upper cavity serves to house the second set of electrical contacts (9); The containers can be stacked alternating between block-A (8) and block-B (10) to form from 2 to 36 chambers, each of these chambers serves as housing for a single set of electrical contacts (9) called pole, which conduct a single signal, be it a control contact (a) (FIG. 6), a current contact (b)(FIG. 6) or a potential contact (c)(FIG. 6), this allows the assembly of multipolar blocks with all possible combinations of contact types, each combination is called a configuration; The geometries and wall thicknesses of the containers allow maintaining a 2500V insulation that have been tested in the laboratory with 1.5 millimeters of wall thickness, each block-A (8) and block-B (10) container has walls (11) (FIGS. 1, 2, 3, 4 and 6) that delimit the corridor (19) (FIGS. 2, 3, 4 and 6) of the passage of the teeth and serve to restrict the lateral movement of the paddle; To close the chamber of the last set of electrical contacts (9), the lower cavity of a block-lid container (12) is used and to close a second upper metal base (13) opposite the lower metal base (1) with the same bolt to lock (5) the ratchet (44) (FIG. 7) and with the same holes to be fixed by means of three threaded rods (14) that cross the block from end to end. The “bastiplas” (2) is not modular, so a different “bastiplas” (2) is required for each block with a different number of poles.

### The Current Contacts

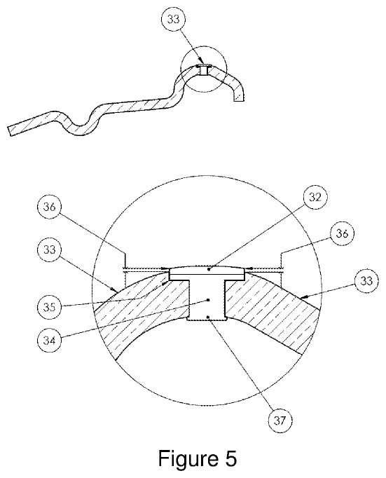

According to FIG. 2, the primary equipment side receiving terminal (15) is joined to a flexible copper cable (16) that at an intermediate point of its length is joined to the primary equipment side contact terminal (17) which is activated. by a torsion spring in the direction of the tooth corridor; and at the other end it is joined to the short contact (18) which has a u-shaped bend that, through a bolt embedded in the container, functions as a slide with linear and rotational movement; which is activated by a torsion spring in the direction of the tooth runner (19) so that the tooth when moving pushes it to make contact with the short bridge (20) which in turn allows a plurality of attached current signals since it is arranged to pass through the lower and upper chambers as shown in FIG. 1 (20); the primary equipment side contact terminal (17) makes contact with the instrument side contact terminal (21) which is also actuated by a torsion spring towards the tooth corridor (19), it is attached to flexible copper cable (22) which in turn joins the instrument side receiving terminal (23), in normal state the contact point (24) of both terminals is performed in a surface region that is a silver inlay (32) (FIG. 5) whose profile is equidistant with the geometric profile (33) (FIG. 5) of the copper sill that forms both contacts, which at the same time serves to create friction with the profile of the tooth that, when moving, separates and insulates them electrically.

### Control and Potential Contacts

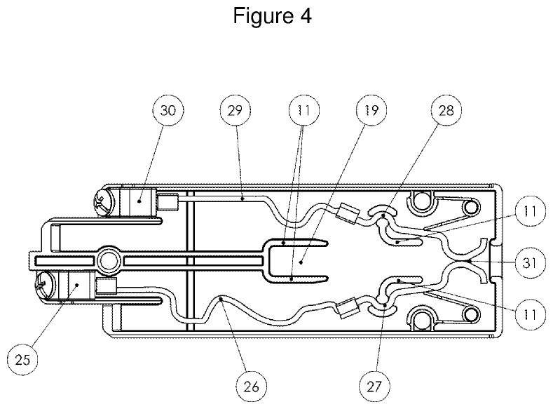

According to FIGS. 3 and 4, the receiving terminal on the primary equipment side (25) is attached to a flexible copper cable (26) and is attached to the contact terminal on the primary equipment side (27), which is activated by a torsion spring in direction to the tooth corridor (19) to make contact with the instrument side contact terminal (28) which is also actuated by a torsion spring towards the tooth corridor (19), is attached to a flexible copper cable (29) which in turn joins the instrument side receiving terminal (30), both terminals have a silver inlay (32) (FIG. 5) at their contact point (31) and their interaction with the tooth is equivalent to described for current terminals.

### Contact Points

According to FIG. 5, a method of inlaying silver (32) at the contact point (24) (FIG. 2) (31) (FIGS. 3 and 4) is a bimetallic copper rivet (34) with a silver head, embedded in a box (35) that houses the head of the bimetallic rivet (34) so that the profile of the head protrudes a distance less than 0.5 mm from the geometric profile (33) of the terminals and the point of contact point is always silver with silver, the equidistance of both profiles is referred to as life of the contact (36) whose wear is caused by the friction of the tooth; and the tailstock of the rivet is forged at both ends (37) to ensure that it is secured in the copper sill.

### Operation Sequence

According to FIG. 6, the contact terminals of the control signals (a), current (b) and potential (c) are arranged along the corridor (19) through which the paddle tooth (50) (FIG. 7) moves to produce the required sequence by advancing the tooth: the control contacts (38) are firstly open when the tooth crosses the line (A); secondly the short contacts, elements (18) and (20) close when the tooth crosses the line (B); thirdly the current contacts (40) are opened when the tooth crosses the line (C); fourthly the potential contacts (41) are opened when the tooth crosses the line (D) at the end of the corridor (19).

### Paddle

According to FIG. 7, the paddle assembly consists of a metal cover (42) attached by screws to a paddle-base container (43) that serves to house the ratchet mechanisms (44) and the trigger (45). an end of the handle (46), a paddle-A container (47) superimposed on the paddle-base container (43); a paddle-B container (49) superimposed on the paddle-A container (47) that together form a chamber that serves to house and fix the guide (48); a paddle-A container (47) superimposed on the paddle-B container (49) that together form a chamber where the first signal composed of a tooth (50) attached to a flexible copper cable (51) by means of a cooper clip (52) and this in turn to a cylindrical terminal (53) which in turn serves as a clip at the internal edge (54) and at the external edge (55) serves to connect “banana type” terminals, this terminal is concentric to a window (57) of the container by means of reliefs (58) on the inside of the window that coincide with the surface of the cylindrical terminal (53) that presses and centers them and is arranged so that its entire body remains inside the window (57) cylindrical container to be electrically isolated from incidental contact with the user; the containers can be stacked alternating between paddle-A container (47) and paddle-B container (49) to house from 2 to 36 signals to complement a block with the same number of signals; to close the last contact, a paddle-B container (49) is used and subsequently a paddle-base container (43) opposite the first, which serves to house a second ratchet mechanism (44) and trigger (45); a metal cover (42) attached to the paddle-base container (43) by screws to protect the mechanism; the handle (46) is housed in a cavity of the paddle-base container (43) to another attached by screws. The assembly of all containers is carried out using tubes with internal thread (59) and screws that tighten the metal covers (42) towards the interior of the block; A square bar (60) (FIG. 8) placed from end to end of the paddle joins both triggers (45).

### Anchor Insurance

According to FIG. 8, the ratchet mechanism (44) and the trigger (45) consists of a square bar (60) that is arranged from end to end of the paddle by means of two friction bearings that consist of a disc (61) with a square perforation concentric to its circumference through which the square bar (60) passes through, housed in a steel box (62) attached by screws to the base container and allows the disc (61) to rotate freely; at the ends, the square bar (60) has two first-order levers whose power arms (63) extend at right angles outward from the container and which act as actuation triggers (45), which its resistance arm (64) makes contact with a second second order lever which in turn receives the power at the end of its power arm (65) and whose resistance is a helical spring (66), housed in the paddle-base container (43), which also has a second toothed arm that has the function of a linear ratchet (44) whose geometries limit the movement of the paddle in both directions when the locking bolt (5) (FIG. 1) enters the slots, until the trigger (45) is activated and pushes the ratchet (44) to release said bolt (5) (FIG. 1), these restrictions in the mechanism allow the paddle to gradually enter the block as well as synchronize the penetration of all the teeth of the paddle, producing the sequence of operation of all signals in discrete steps.

1. An auxiliary multipolar device for testing electrical instruments that houses inside a plurality of electrical contacts that interrupt control and potential signals and short-circuit and interrupt current signals between a primary equipment and a measurement equipment, control and protection instruments, which has terminals on a back with screws, to connect electrical signals, housed in a plurality of insulating containers organized in a modular way for a plurality of signal combinations by a frame on the front that has viewing windows access to each signal that allows the insertion of a signal shunt or a test paddle to switch the electrical signals, wherein the sets of current signal contacts have a terminal joined by a flexible cable and clip made of copper, on the side instrument with a device to maintain contact with a profile of a tooth throughout an insertion or an extraction path, in addition to being arranged to make contact with the short circuit terminal prior to the tooth making contact with the contact terminals of the currents, that in addition the contact points between the contact terminals of the control signals, current and potential are a material of high electrical conductivity in the form of an inlay, that in addition the containers that make up the block and the paddle are modular assemblies that they allow assemblies of 2 to 36 signals to be made, which also has a device to insert the paddle sequentially in discrete advances and anchor in each step of said sequence and a device for the user to unlock each step of the sequence, which also has a device to isolate at 2500 V each pole.

2. The auxiliary multipolar device for testing electrical instruments according to claim 1, wherein the contact terminals of the control, current and potential signals are made of a material with high electrical conductivity, in the form of an inlay, which is made of pure silver, and which has a stem for fastening the rivet to the contact terminals, and whose rivet head is arranged to coincide with the geometric surface of the contact terminal and allow the free movement of the teeth.

3. The auxiliary multipolar device for testing electrical instruments according to claim 1, wherein the containers are made of a dielectric material that allows isolating 2500V in 1.5 millimeters of wall.

4. The auxiliary multipolar device for testing electrical instruments according to claim 1, wherein the body of the paddle is assembled by two types of modular containers that alternately allow the cavities to be formed in which the tooth of each signal is fixed together by a flexible support to a cylindrical terminal with a device to be electrically isolated from direct contact with the user and arranged to receive a banana-type connector with an insulating membrane.

5. The auxiliary multipolar device for testing electrical instruments according to claim 1, wherein the sequential insertion of the paddle can be through a pair of linear ratchets whose teeth are arranged with a device to produce a bidirectional lock at each end of the paddle and to enter two cavities at the ends of the block, inside which there is a bolt arranged so that the advance of both ratchets is synchronous and blocks the ratchets in each step, which in addition the unlocking of the ratchets is through a set of two triggers joined by a square rod that serves as a pivot and as a movement synchronizer for both triggers; which also has a holding device and move within the base containers of the paddle.

6. The auxiliary device for testing multipolar electrical instruments according to claim 1, wherein the set of electrical contacts of the current signals have an independent short circuit contact connected to the primary equipment side with a device to have a linear movement and rotational towards the short circuit bridge and means to remain in the tooth corridor normally, arranged between the main contact terminals and the chamber window and for the tooth to activate its movement by sliding along the corridor and the short circuit occurs before the tooth opens the main contact terminals.
